(19) United States
(12) Patent Application Publication
(10) Pub. No.: US 2021/0059370 A1
(43) Pub. Date: Mar. 4, 2021

(54) SUPPORT FOR ELECTRONIC DEVICE

(71) Applicant: C2 Wireless and Accessories LLC, Irvine, CA (US)

(72) Inventors: Carlos Del Toro, Whittier, CA (US); Peter Tu, Irvine, CA (US); Elva Huang, Brea, CA (US)

(21) Appl. No.: 16/930,077

(22) Filed: Jul. 15, 2020

Related U.S. Application Data
(60) Provisional application No. 62/891,844, filed on Aug. 26, 2019.

(51) Int. Cl. A45C 11/00; F16M 13/00; H05K 5/02

(52) U.S. Cl. CPC A45C 11/00; F16M 13/005; A45C 2200/15; A45C 2011/002; A45C 2011/003; H05K 5/0204

(57) ABSTRACT

Disclosed is a support device that can be connected either to an accessory case for an electronic device, or directly to the electronic device. The support device uses a flexible finger loop that is held in place by a track guide connected to the flexible finger loop that moves along a track in a frame of the support device. Balancing forces in the flexible finger loop hold a kick stand in place to support the electronic device or accessory case in a stable position.

### BACKGROUND

Various types of electronic accessories and electronic devices exist today, including cell phones, small computers and various types of personal communication devices. Protective cases have also been designed for these devices and other electronic devices. These accessories have been found to be extremely useful, and their uses have become a common part of the daily life of many people.

### SUMMARY

An embodiment of the present invention may therefore comprise a low profile support for an electronic device or electronic device accessory comprising: a kick stand that extends from the support and that can be retracted into the support; a flexible finger loop made from a thermo-polyurethane having a first end that is connected to the kick stand that generates a force on the kick stand when the kick stand is extended from the support and has a stiffness that is sufficient to hold the kick stand in a predetermined position; a frame attached to a first end of the kick stand; a track formed in v frame; a track guide that fits in the frame and moves in the track, the track guide attached to a second end of the flexible finger loop; a retention device formed in the track guide and the track that releasably hold the track guide in a predetermined position on the track so that the flexible finger loop forms a loop and forces the kick stand to the predetermined position.

An embodiment of the present invention may further comprise a method of supporting an electronic device using a support device coupled to the electronic device or an accessory case for the electronic device comprising: providing a kick stand which extends from the support device to support the electronic device; providing a frame that provides a connection to the electronic device or the accessory case; mounting a track guide in a rail disposed in the frame; bonding the support device to the electronic device or the accessory case; attaching the track guide to a first end of a flexible finger loop, the flexible finger loop made from a thermo-polyurethane; attaching a second end of the flexible finger loop to the kick stand so that the track guide moves in the rail and the flexible finger loop flexes in a loop shape and the flexible finger loop is sufficiently stiff to hold the kick stand in a predetermined position relative to the frame; placing a flexible retention device in the track guide and the track to releasably secure the track guide in the track.

### BRIEF DESCRIPTION OF THE DRAWINGS

FIG. 1 is a perspective view of an embodiment of an accessory case having a support device connected to the accessory case.

FIG. 2 illustrates an embodiment of the support device in an open position.

FIG. 3 is a side view of an embodiment of the accessory case in an upright position and an embodiment of the support device.

FIG. 4 is another side view of the accessory case in a horizontal position and the support device.

FIG. 5 is an exploded view illustrating the various parts of and embodiments of the support device in a perspective view.

FIG. 6 is a partial cutaway view of the support device in an open position.

FIG. 7 is a close-up view of the support device.

FIG. 8 is a perspective view of the kick stand, the flexible finger loop and track guide.

FIG. 9 is a perspective view of the flexible finger loop, track guide and frame.

FIG. 10 is a close-up view of the track guide.

FIG. 11 is a detailed view of the track guide and track in which the track guide moves.

### DETAILED DESCRIPTION OF THE EMBODIMENTS

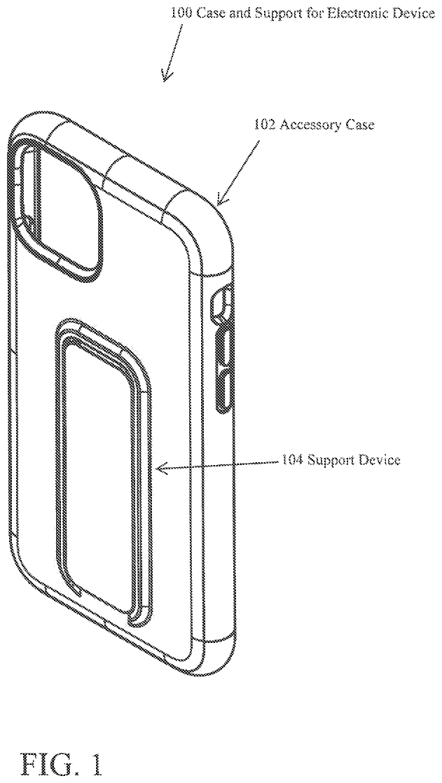

FIG. 1 is a schematic perspective view of an embodiment of a case and support 100 for an electronic device. An accessory case 102 is used to hold and secure an electronic device, such as a smart phone, small computer, a tablet computer, an electronic picture frame, a standard picture frame, an LCD screen, or other handheld electronic device, or any device that needs to be supported. Connected to the accessory case 102 is a support device 104. Support device 104 can be ultrasonically welded, glued, co-molded or otherwise bonded to the accessory case 102.

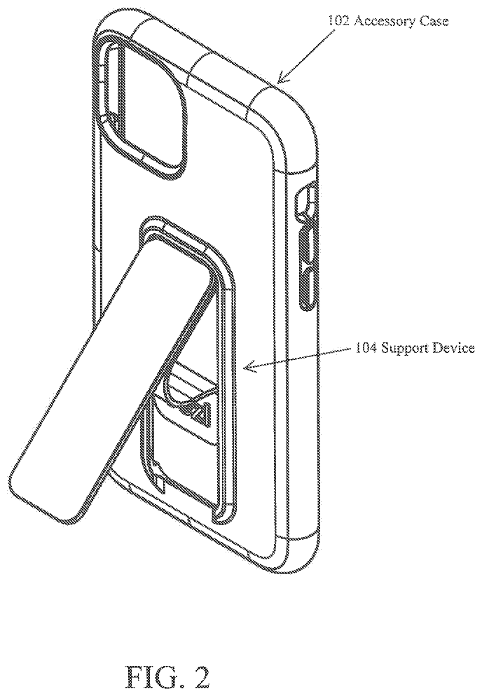

FIG. 2 is an illustration of an embodiment of an accessory case 102 and a support device 104 in an open position.

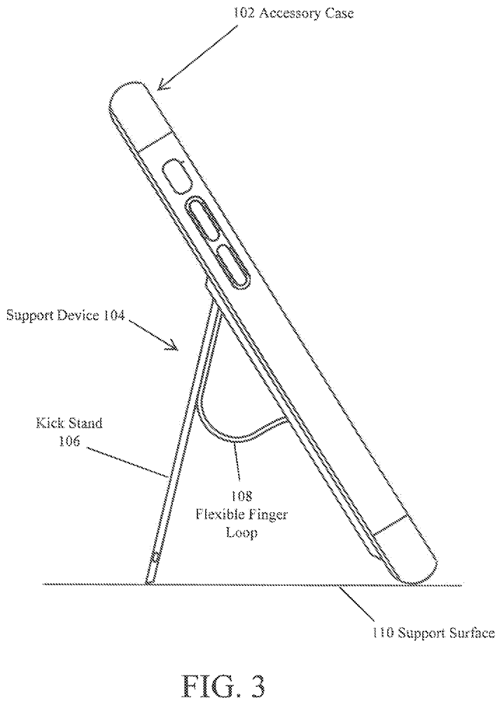

FIG. 3 illustrates the accessory case 102 in a side view, showing the support device 104 in an open position. A kick stand 106 and the bottom of the accessory case 102 rests upon a support surface 110. The flexible finger loop 108 holds the kick stand 106 in the stationary, open position, as shown in FIG. 3.

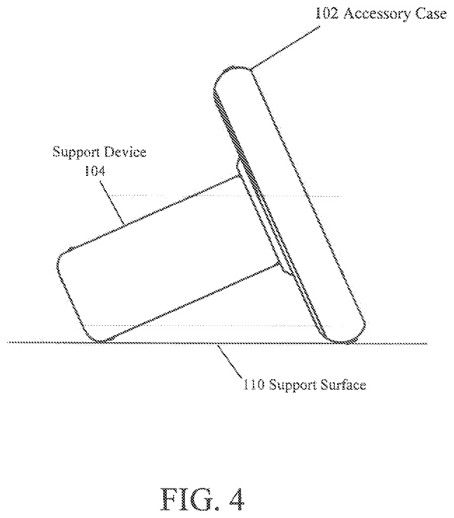

FIG. 4 is another side view of the accessory case 102 turned on its side. The support device 104 and the bottom of the accessory case 102 rest on the support surface 110. As a result, the support device 104 can support the accessory case 102 in an upright position, as shown in FIG. 3, and a horizontal position, as illustrated in FIG. 4.

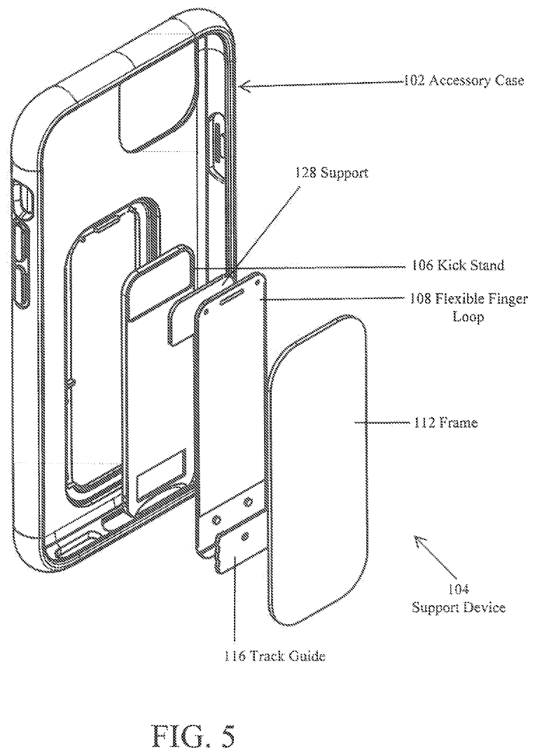

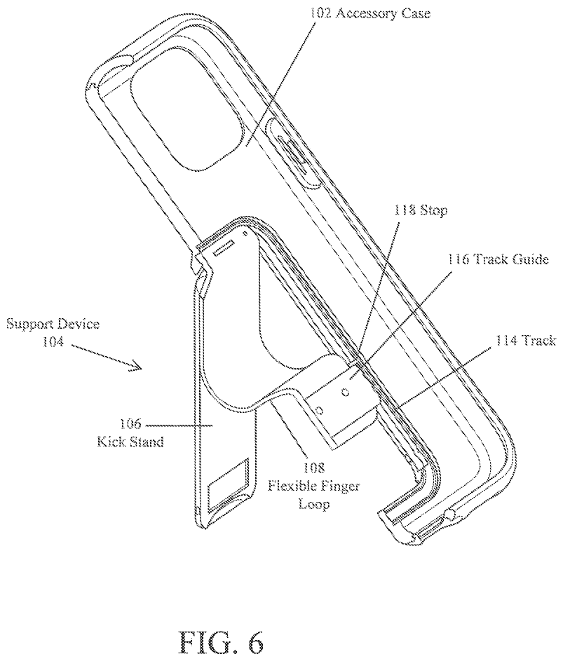

FIG. 5 is an exploded view of the support device 104 and the accessory case 102. As illustrated in FIG. 5, the flexible finger loop 108 is attached to a kick stand 106 using a support 128. The size of the support 128 and the length of the attachment of support 128 to the kick stand 106 and the flexible finger loop 108 affect the stability of the support device 104. The kick stand 106 is connected by a hinge flange (not shown) to the support 128, which in turn is attached, or otherwise ultrasonically welded, co-molded, or adhesively bonded, to the flexible finger loop 108. Co-molding is a process of injection molding. For example, TPU can be injection molded on a prefabricated PC piece. Various means of attachment can be used, including the use of bonding materials, IR heat welding, ultrasonic welding, co-molding or use of various types of bonding materials. In a similar fashion, track guide 116 is connected to the flexible finger loop 108. The upper end of the kick stand 106 is connected to the top portion of the frame 112. The track guide 116 is mounted in track 114 (FIG. 6) in the frame 112, as disclosed below.

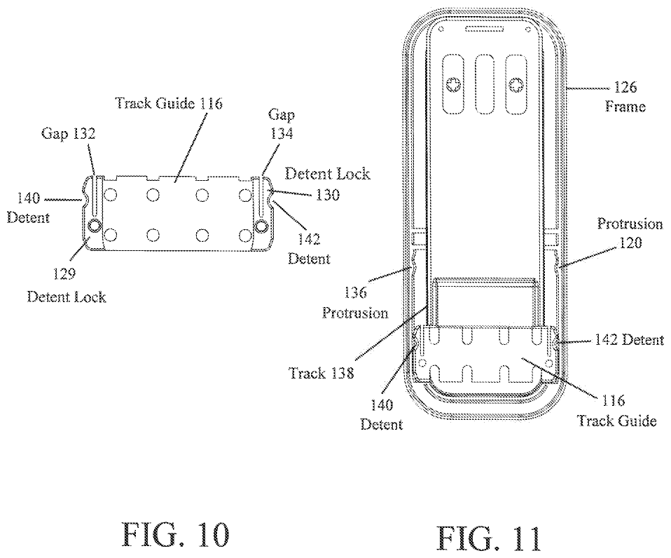

The flexible finger loop 108, as shown in FIG. 5, may be constructed of a thermo-polyurethane (TPU), which can have a high degree of flexibility and elasticity. Thermo-polyurethane (TPU) is also referred to as thermoplastic polyurethane, which is a class of plastics that have elasticity. Thermo-polyurethane is a thermoplastic elastomer consisting of linear segmented block-copolymers composed of hard and soft segments. Block-copolymers consist of alternating sequences of hard and soft segments or domains formed by the reaction of diisocyanates with short-chain diols, and diisocyanates with long-chain diols. By varying the ratios of the short-chain diols and the long-chain diols, the structure and molecular weight of the reaction components can be changed to produce a wide variety of TPU structures. Urethane chemists can therefore fine-tune a TPU structure to achieve the desired properties, such as flexibility, elasticity and durability, by varying the ratio of hard to soft segments. Accordingly, the TPU structure consists of linear polymeric chains in block-structures. Low polarity segments are a long-chain, and are soft segments, which alternate with shorter, high polarity segments, which are hard segments. These segments are linked together with covalent links to form the block-copolymers. The long-chain segments create greater flexibility, while the short-chain segments reduce the flexibility of the TPU product to produce more stability. In accordance with the present invention, the flexible finger loop 108 has to be sufficiently flexible to allow a user to bend the flexible finger loop 108 easily to allow the kick stand 106 to be easily extended from frame 126. However, a sufficient force must be generated on the kick stand 106 and the flexible finger loop 108 has to be sufficiently stiff to hold the kick stand 106 in place with the weight of the device when the flexible finger loop 108 is extended and the track guide 116 is secured in the track 138 with the retention devices illustrated in FIGS. 10 and 11. As such, the TPU can be fabricated to both have flexibility to easily allow a user to flex the flexible finger loop 108, while still providing a sufficient force and having a sufficient stiffness to hold the kick stand 106 at a predetermined angle to support the electronic device. A desired range of the TPU to create the desired flexibility and stability is a shore durometer of 95 to 105. Of course, lesser shore durometers and greater shore durometers that vary slightly from this range may also provide the desired stiffness and flexibility, based upon the length of the flexible finger loop 108 and the size of the support 128. The kickstand 106, support 128, frame 112 and track guide 116 can be made from polycarbonate material, which is substantially stiffer than the thermo-polyurethane.

FIG. 6 is a cutaway view, illustrating the accessory case 102 and portions of the support device 104. As illustrated in FIG. 6, the kick stand 106 is in an open position, and the flexible finger loop 108 forms a loop, which supports the kick stand 106. The loop in the flexible finger loop 108 creates an outward force on kick stand 106, created by the track guide 116 forcing the flexible finger loop into the looped configuration, which is balanced by the stiffness of flexible finger loop 108 which resists the bending force. This balancing of forces holds the kick stand in a stable, open position. The track guide 16 is mounted in a track 114 in the interior portion of the frame 112. Stop 118 prevents the track guide 116 from moving past the stop 118 in track 114.

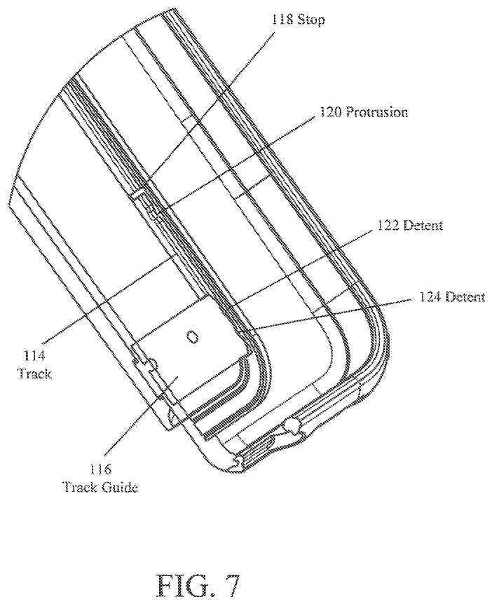

FIG. 7 is a close-up cutaway view of the track guide 116 and track 114. The track guide 116 moves along the track 114 until it reaches the stop 118. The protrusions 120 fit within the detents 122, 124, so that the track guide 116 is held in place. This allows the kick stand 106 to be extended to a desired angle and held at that angle by the flexible finger loop 108, which stabilizes the kick stand 106 to hold the kick stand 106 in place.

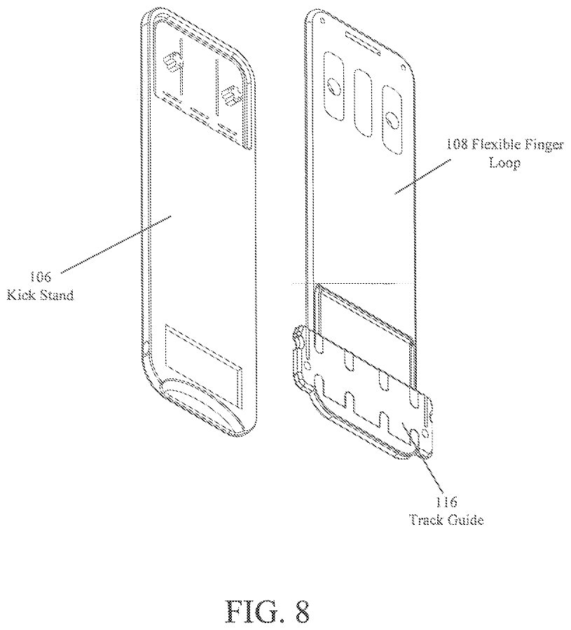

FIG. 8 is a bottom view of the kick stand 106 and flexible finger loop 108. The track guide 116 is mounted on the flexible finger loop 108. The kick stand 106 is ultrasonically welded or otherwise attached to the flexible finger loop at the top portion of FIG. 8.

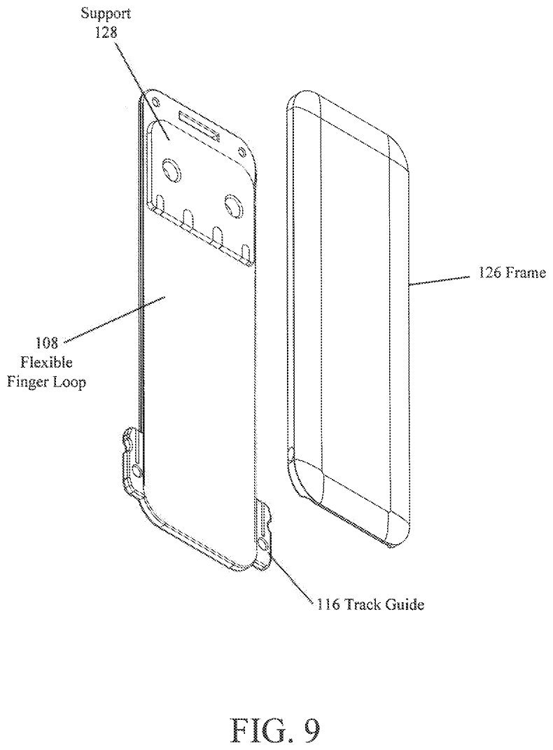

FIG. 9 is a perspective view of the flexible finger loop 108 and the frame 126. A support 128 is connected to the flexible finger loop, which is then connected at the top portion to a frame 126, as shown in FIG. 9. Track guide 116 is inserted into the frame 126 to complete the construction of the support device 104.

FIG. 10 is a close-up view of the track guide 116. As illustrated in FIG. 10, retention devices are illustrated that releasably hold the track guide 116 at a predetermined location on track 138. For example, detent lock 129 is positioned on a first side of the track guide 116 and detent lock 130 is positioned on the opposite side of the track guide 116. Gap 132 provides an opening so that the detent lock can flex and the detent can engage the protrusion 136 (FIG. 11). The flexure of the detent lock 129 holds the track guide 116 in position on the track 138. Gap 134 allows the detent lock 130 to flex so that the detent 142 engages the protrusion 120 and holds the track guide 116 in position on the rail 138. Of course, any type of retention device can be used to hold the track guide 116 at a predetermined location on track 114. The advantage of the detent locks 129, 130 is that the detent locks 129, 130 are built into the track guide 116 and utilize the flexibility of the plastic of the track guide 116.

FIG. 11 is a top cutaway view of the track guide 116 disposed in the frame 126. As illustrated in FIG. 11, the track 138 includes protrusions 136, 120, that engage the detents 140, 142, respectively, of the track guide 116. In this manner, the track guide 116 can be releasably fixed in a predetermined location on the track 138.

Accordingly, the embodiments of the present invention provide a support for electronic devices that can be attached to an accessory case 102 or directly on the electronic device itself. The support device 104 provides a kick stand 106 to support the electronic device in either a lengthwise or horizontal position for viewing the device. A flexible finger loop 108 is used to hold the kick stand 106 in place. A track guide 116 is used that is disposed in a track 114 that locates the flexible finger loop 108 in a predetermined position. The flexibility of the finger loop 108 provides a force on the kick stand 106 that holds the kick stand 106 in a predetermined, stable position. A stop 118 is placed in the track 114 to prevent the track guide 116 from moving once the kick stand 106 is in place. The support device 104 provides an inexpensive and easy to use device that has a low profile so that electronic devices, such as smart phones, are not burdened with thick devices that prevent the easy transport of the electronic device. Since both stiff and flexible plastics are used, the stability and ease of use can be controlled. The support can be produced inexpensively, using standard molding and bonding techniques.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A low profile support for an electronic device or electronic device accessory comprising:
a kick stand that extends from said support and that can be retracted into said support;
a flexible finger loop made from a thermo-polyurethane having a first end that is connected to said kick stand that generates a force on said kick stand when said kick stand is extended from said support and has a stiffness that is sufficient to hold said kick stand in a predetermined position;
a frame attached to a first end of said kick stand;
a track formed in said frame;
a track guide that fits in said frame and moves in said track, said track guide attached to a second end of said flexible finger loop;
a retention device formed in said track guide and said track that releasably hold said track guide in a predetermined position on said track so that said flexible finger loop forms a loop and forces said kick stand to said predetermined position.

2. The support of claim 1 wherein said retention device comprises at least one flexible arm on said track guide and either a detent or a protrusion on said at least one flexible arm that engage either a detent or a protrusion on said track.

3. The support of claim 2 further comprising a flexible latch that secures said kick stand to said frame in a closed position.

4. The support of claim 3 wherein said frame is made from a polycarbonate.

5. A method of supporting an electronic device using a support device coupled to said electronic device or an accessory case for said electronic device comprising:
providing a kick stand which extends from said support device to support said electronic device;
providing a frame that provides a connection to said electronic device or said accessory case;
mounting a track guide in a rail disposed in said frame;
bonding said support device to said electronic device or said accessory case;
attaching said track guide to a first end of a flexible finger loop, said flexible finger loop made from a thermo-polyurethane;
attaching a second end of said flexible finger loop to said kick stand so that said track guide moves in said rail and said flexible finger loop flexes in a loop shape and said flexible finger loop is sufficiently stiff to hold said kick stand in a predetermined position relative to said frame;
placing a flexible retention device in said track guide and said track to releasably secure said track guide in said track.

6. The method of claim 5 further comprising using flexible detents or flexible protrusions on said track guide to releasably hold said track guide in a predetermined position on said track.

7. The method of claim 6 further comprising making said kick stand and said frame from polycarbonate.
